(19) United States
(12) Patent Application Publication
(10) Pub. No.: US 2019/0178456 A1
(43) Pub. Date: Jun. 13, 2019

(54) SELF-GENERATED LIGHTING FIXTURE

(71) Applicant: Heiji NIIYAMA, Tokyo (JP)

(72) Inventor: Heiji NIIYAMA, Tokyo (JP)

(21) Appl. No.: 16/326,164

(22) PCT Filed: Aug. 15, 2017
(86) PCT No.: PCT/JP2017/029337

§ 371 Date: Feb. 15, 2019

(30) Foreign Application Priority Data
Aug. 17, 2016 (JP) 2016-171257

(51) Int. Cl. F21S 9/03; F21S 9/04; F21V 9/08

(52) U.S. Cl. CPC F21S 9/032; F21W 2131/103; F21V 9/08; F21S 9/04

(57) ABSTRACT

A self-generated lighting fixture, including: a light source for illumination that emits light upon receiving supply of electric power; a transparent solar cell that absorbs light energy to generate electricity; and a power control unit that controls the electric power supplied to the light source and includes commercial electric power as one of electric powers to be controlled, wherein the light source has a first light source and a second light source provided independently of each other, the transparent solar cell absorbs a summed light energy from both the first light source and the second light source to generate electricity, and the power control unit supplies the commercial electric power to the first light source and supplies the electric power generated by the transparent solar cell to the second light source.

### TECHNICAL FIELD

The present invention relates to a self-generated lighting fixture capable of absorbing light energy by a transparent solar cell, the light energy being radiated from a light source for illumination, and capable of self-generating photovoltaic power by a photovoltaic effect.

### DESCRIPTION OF RELATED ART

Until now, photovoltaic power generation is a device that absorbs UV lights and light energy of daytime sunlight and self-generates photovoltaic power by the photovoltaic effect as its name suggests, and there has been no high interest in power generation of reusing light energy radiated from a light source for illumination instead of the daytime sunlight.

In recent years, as a light source for signboard illumination, a signboard illumination device using a LED (Light Emitting Diode) light source instead of a fluorescent lamp or a mercury lamp has been disclosed by the present inventor (see Patent Document 1).

Further, transparent solar cells utilizing daytime sunlight are also disclosed (see Patent Documents 2, 3, 4).

### PRIOR ART DOCUMENT

### Patent Document

### [Patent Document 1] Japanese Patent No. 5189217

### [Patent Document 2] Japanese Patent Application Laid-Open No. 2005-129987

### [Patent Document 3] Japanese Patent Application Laid-Open No. 2009-229975

### [Patent Document 4] Japanese Patent Application Laid-Open No. 2011-119455

### SUMMARY OF THE INVENTION

### Problem to be Solved the Invention

So far, much efforts are made to reduce power consumption of a light source for illumination, but it has been neglected to effectively reuse a self-radiated light energy by the light source for illumination.

Further, in the signboard illumination device described in Patent Document 1, although much efforts are made to reduce power consumption, there is no mentioning about the reuse of the light energy radiated from a LED light source.

In a mobile phone described in Patent Document 2, a problem is that there is a large variation in power generation amount due to weather, because the light energy of sunlight is used, although an entire housing is constituted of a transparent solar cell.

Further, in an electric bulletin board described in Patent Document 3, a problem is that power generation amount is extremely reduced in a case of rainy weather etc., because the light energy of sunlight is used as described above.

Further, in an organic EL device including a solar cell described in Patent Document 4, a problem is that there is a variation in power generation capacity due to the weather and stable power generation cannot be expected, because the light energy of daytime sunlight is absorbed to generate electricity.

An object of the present invention is to provide a self-generated lighting fixture capable of reusing a light energy radiated from a light source for illumination to self-generate electricity, and capable of realizing further power saving, in view of a long-term power failure due to an accident at nuclear power plants in Fukushima Prefecture, a surge of electricity price and a consciousness of power saving thereafter.

### Means for Solving the Problem

### (First Aspect)

According to a first aspect of the present invention, there is provided a self-generated lighting fixture, including:

a light source for illumination that emits light upon receiving supply of electric power;

a transparent solar cell that absorbs light energy to generate electricity; and

a power control unit that controls electric power supplied to the light source and includes commercial electric power as one of electric powers to be controlled,

wherein the light source has a first light source and a second light source provided independently of each other,

the transparent solar cell absorbs a summed light energy from both the first light source and the second light source to generate electricity, and

the power control unit supplies the commercial electric power to the first light source and supplies the electric power generated by the transparent solar cell to the second light source.

### (Second Aspect)

According to a second aspect of the present invention, there is provided a self-generated lighting fixture, including:

a light source for illumination that emits light upon receiving supply of the electric power;

a mount-type substrate on which the light source is mounted;

a transparent solar cell that absorbs light energy to generate electricity; and

a power control unit that controls electric power supplied to the light source and includes commercial electric power as one of electric powers to be controlled,

wherein the light source includes a first light source mounted on one main surface of the mount-type substrate, a second light source mounted on the other main surface of the mount-type substrate so as to emit light toward the opposite side of the first light source,

the transparent solar cell absorbs light energy radiated from the first light source to generate electricity, and

the power control unit supplies the commercial electric power to the first light source and supplies the electric power generated by the transparent solar cell to the second light source.

### (Third Aspect)

According to a third aspect of the present invention, there is provided a self-generated lighting fixture, including:

a light source for illumination that emits light upon receiving supply of electric power;

a transparent solar cell that absorbs light energy to generate electricity;

a power control unit that controls electric power supplied to the light source and includes commercial electric power as one of electric powers to be controlled; and

a power storage device including a storage battery that stores electricity upon receiving supply of the electric power from the power control unit, and supplies the electric power stored in the power storage battery,

wherein the transparent solar cell absorbs the light energy radiated from the light source to generate electricity,

the power control unit captures the commercial electric power and the electric power generated by the transparent solar cell, and supplies the captured electric power to the power storage device, and

the power storage device has a detecting function of detecting stop of supply of the electric power from the power control unit, and/or power failure, in addition to on/off function of a power switch, and when the stop of supply of the electric power from the power control unit and/or power failure is detected by the detecting function, the power storage device has an endless function of always turning on the light source by continuously supplying the electric power stored in the storage battery to the light source, and resuming supply of the electric power to the light source upon receiving supply of the electric power from the power control unit, the electric power being generated by the transparent solar cell by absorption of the light energy radiated from the light source during the on state.

### (Fourth Aspect)

According to a fourth aspect of the present invention, there is provided a self-generated lighting fixture, including:

a light source for illumination that emits light upon receiving supply of electric power;

a panel having an illumination target surface irradiated with light energy from the light source; and

a transparent solar cell that absorbs the light energy to generate electricity,

wherein the light source is installed so as to be obliquely inclined with respect to the illumination target surface so that an illumination target surface of the panel is irradiated obliquely with the light energy,

an irradiation target surface of the panel is disposed outward, and

the transparent solar cell is formed in a planar shape on the irradiation target surface, and both the light energy radiated from the light source and the light energy of the sunlight are absorbed to generate electricity.

### (Fifth Aspect)

According to a fifth aspect of the present invention, there is provided a self-generated lighting fixture, including:

a light source for illumination that emits light upon receiving supply of electric power;

a transparent solar cell that absorbs light energy to generate electricity; and

a power control unit that controls electric power supplied to the light source and includes commercial electric power as one of electric powers to be controlled,

wherein the transparent solar cell absorbs the light energy radiated from the light source to generate electricity,

the power control unit supplies summed power of the commercial electric power and the electric power generated by the transparent solar cell to the light source, and

the light source irradiates light energy by supplying the summed electric power.

### Advantage of the Invention

According to the present invention, it is possible to provide a self-generated lighting fixture capable of reusing light energy radiated from a light source for illumination to self-generate electricity, and capable of realizing further power saving.

### BRIEF DESCRIPTION OF THE DRAWINGS

FIG. 1A is a schematic plan view showing a configuration of a surface mount-type LED package.

FIG. 1B is a cross-sectional view taken along the line A-A of FIG. 1A.

FIG. 1C is a cross-sectional view showing another configuration of the surface mount-type LED package.

FIG. 2 is a schematic perspective view showing an arrangement of a transparent UV cut film, an organic thin film transparent solar cell and a purple LED module.

FIG. 3A is a schematic perspective view of a purple LED module including a frame of a self-generated lighting fixture according to a first embodiment of the present invention.

FIG. 3B is a sectional view taken along the line A-A of FIG. 3A.

FIG. 3C is a schematic view showing a configuration example of an electric circuit of a self-generated lighting fixture according to a first embodiment of the present invention.

FIG. 4A is a perspective view including a frame of a self-generated lighting fixture according to a second embodiment of the present invention.

FIG. 4B is a cross-sectional view taken along the line A-A of FIG. 4A.

FIG. 4C is a cross-sectional view taken along the line B-B of FIG. 4B.

FIG. 4D is a schematic view showing a configuration example of an electric circuit of a self-generated lighting fixture according to a second embodiment of the present invention.

FIG. 5A is a perspective view including a frame of a self-generated lighting fixture according to a third embodiment of the present invention.

FIG. 5B is a cross-sectional view taken along the line A-A of FIG. 5A.

FIG. 5C is a schematic view showing a configuration example of an electric circuit of a self-generated lighting fixture according to a third embodiment of the present invention.

FIG. 6A is a perspective view including a frame of a self-generated lighting fixture according to a fourth embodiment of the present invention.

FIG. 6B is a cross-sectional view taken along the line A-A of FIG. 6A.

FIG. 6C is a schematic view showing a configuration example of an electric circuit of a self-generated lighting fixture according to a fourth embodiment of the present invention.

FIG. 7A is a perspective view including a frame of a self-generated lighting fixture according to a fifth embodiment of the present invention.

FIG. 7B is a cross-sectional view taken along the line A-A of FIG. 7A.

FIG. 7C is a schematic view showing a configuration example of an electric circuit of a self-generated lighting fixture according to a fifth embodiment of the present invention.

FIG. 8A is a perspective view including a frame of a self-generated lighting fixture according to a sixth embodiment of the present invention.

FIG. 8B is a cross-sectional view taken along the line A-A of FIG. 8A.

FIG. 8C is a schematic view showing a configuration example of an electric circuit of a self-generated lighting fixture according to a sixth embodiment of the present invention.

### DETAILED DESCRIPTION OF THE INVENTION

Hereinafter, embodiments of the present invention will be described in detail with reference to the drawings. Note that in the specification of the present application, all the matters described in the specification, the scope of claims and the drawings of the basic application No. 2016-171257 are stated without omission, and the matters disclosed in the basic application can be added to the specification, claims, and drawings of the present application as necessary.

### (Configuration of LED Package)

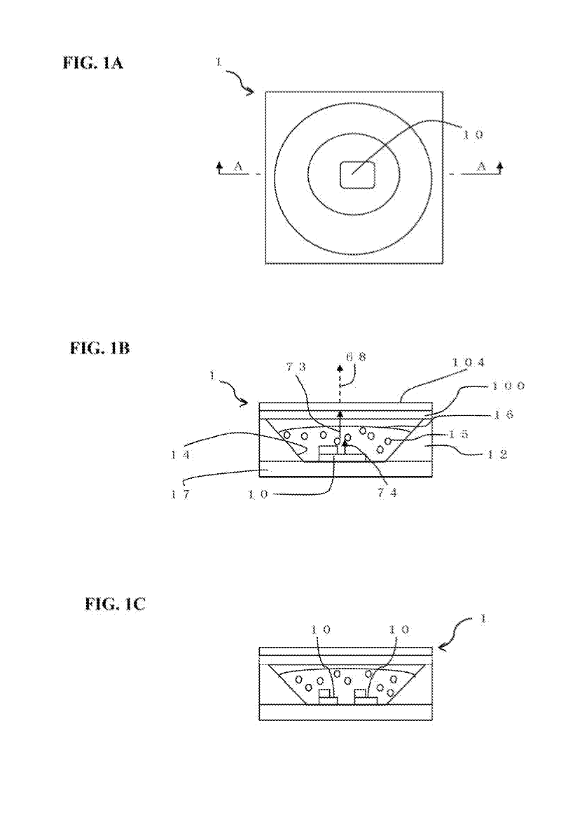

First, a configuration of an LED package used in an embodiment of the present invention will be described with reference to FIGS. 1A, 1B, and 1C. FIG. 1A is a schematic plan view showing a configuration of a surface mount-type LED package, and FIG. 1B is a cross-sectional view taken along the line A-A of FIG. 1A.

In this embodiment, as shown in FIG. 1A and FIG. 1B, a surface mount-type purple LED package 1 is used as an LED package. The purple LED package 1 includes: a cavity 12 molded from ceramic or resin; a purple LED element 10 mounted in the cavity 12; a reflector 14 formed on the inner surface of the cavity 12; a sealing material 15 filling the inside of the cavity 12; a condenser lens 16; LED substrate 17; an organic thin film transparent solar cell 100; and a transparent UV cut film 104. The sealing material 15, the condenser lens 16, the organic thin film transparent solar cell 100, and the transparent UV cut film 104 are stacked in this order on the purple LED element 10.

The reflector 14 reflects purple light energy 74 radiated from the purple LED element 10 to the front surface (upward in FIG. 1B).

The sealing material 15 seals the purple LED element 10, and includes a silicone resin containing R (red) G (green) B (blue) phosphors. For the sealing material 15, it is preferable to use a silicone resin having ultraviolet resistance and heat resistance in which RGB phosphors for simultaneous additive color mixture are dispersed.

The purple LED element 10 is mounted on the LED substrate 17.

The purple LED element 10 radiates purple light energy 74. The purple LED package 1 emits and radiates simultaneous additive white light energy 68, by combining the purple light energy 74 radiated from the purple LED element 10 and the RGB phosphors contained in the sealing material 15.

The organic thin film transparent solar cell 100 absorbs white light energy 68 and purple light energy 74, and generates a photovoltaic power by a photovoltaic effect.

The transparent UV cut film 104 is formed just outside the organic thin film transparent solar cell 100 as seen from the purple LED element 10. The transparent UV cut film 104 absorbs and eliminates UV lights which are transmitted through the organic thin film transparent solar cell 100 and which cannot be completely absorbed by the organic thin film transparent solar cell 100. Therefore, the light energy passing through the transparent UV cut film 104 becomes the white light energy 68 which does not contain UV lights.

Note that in this embodiment, the purple LED package 10 and the organic thin film transparent solar cell 100 are used to constitute the purple LED package 1. However, the configuration is not limited thereto, and for example, a blue LED element and a dye sensitized transparent solar cell may be used, or an LED package may be constituted by a combination of other LED elements and a transparent solar cell. Further, in this embodiment, the term “transparent” means not completely transparent that transmits 100% of visible light, but shows transparency to the extent that visible light is transmitted to some extent, for example, 60% or more.

Further, in the purple LED package 1, white light energy 68 for obtaining the whole visible light region with phosphor emission, is realized by radiating the purple light energy 74 radiated from the purple LED element 10 toward the RGB phosphors contained in the sealing material 15, that is, by simultaneous additive color mixture utilizing three primary colors of light. Therefore, color reproducibility is much higher, and it is easy to approximate Ra (average color rendering index) to 100 by adjusting increase/decrease of each phosphor of RGB, compared to a method of emitting and radiating pseudo white light in a combination of a blue LED element and a yellow phosphor which have been mainstream so far. Further, light emission of light energy such as red, green, blue, yellow, etc. other than white light can be easily controlled by adjusting the increase/decrease of each phosphor of RGB. Further, the purple light energy 74 is radiated from the purple LED element 10 as the light energy 68 for emitting white light by simultaneous additive color mixture with RGB phosphors, or for emitting a color that can be obtained by the simultaneous additive color mixture. The purple light energy 74 is also radiated as UV lights (UV light energy 73).

In this embodiment, the purple LED element 10 is employed as the LED element. However, other LED elements, for example, a near UV light LED element, a blue LED element, or a near infrared LED element may also be employed. Further, in this embodiment, a face-up type is employed as a mounting structure of the purple LED element 10 mounted in the cavity 12 on the LED substrate 17. However, face-down type may also be employed.

Further, as shown in FIG. 1B and FIG. 1C, the number of the purple LED elements 10 used for the purple LED package 1 may be one or plural. The condenser lens 16 and the transparent UV cut film 104 are not indispensable as the purple LED package 1, and may be provided as necessary.

### (Configuration of Transparent Solar Cell)

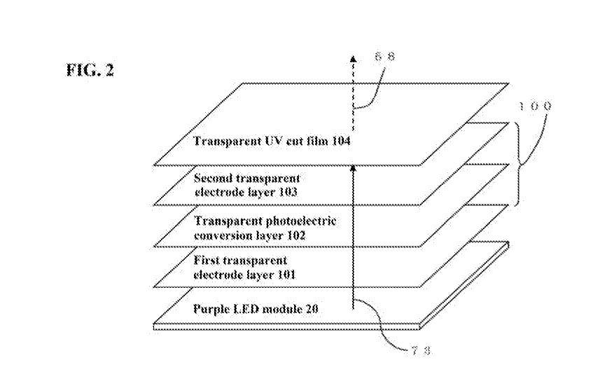

FIG. 2 is a schematic perspective view showing the arrangement of the transparent UV cut film, the organic thin film transparent solar cell and the purple LED module.

As shown in FIG. 2, the organic thin film transparent solar cell 100 is constituted of a first transparent electrode layer 101, a transparent photoelectric conversion layer 102, and a second transparent electrode layer 103, as seen from the purple LED module 20, and are stacked in this order. The purple LED module 20 is formed by connecting a plurality of purple LED packages 1 used in this embodiment, and emits UV light (UV light energy 73) together with the white light energy 68 by simultaneous additive color mixture. The organic thin film transparent solar cell 100 generates high photovoltaic power by adjusting an amount of UV light by increase/decrease of each phosphor of RGB. The organic thin film transparent solar cell 100 absorbs the UV light energy 73 radiated from the purple LED module 20 to generate electricity by the photovoltaic effect. The photovoltaic power which is self-generated by the organic thin film transparent solar cell 100 is supplied to the purple LED module 20 via a DC controller not shown, or stored in a secondary lithium ion storage battery (not shown).

Note that a voltage of the photovoltaic power which is self-generated by the organic thin film transparent solar cell 100 is affected by an amount of incident light of the UV light energy 73, and therefore it is impossible to use the voltage as it is. Therefore, a DC controller is provided, to control the voltage generated by the organic thin film transparent solar cell 100 so as to be compatible with a scheduled supply destination. The DC controller controls the generated voltage so that the supply destination of the voltage generated by the organic thin film transparent solar cell 100 is compatible with each supply destination, for example, the generated voltage is compatible with each supply destination of the purple LED element 10, the lithium ion storage battery or the like. Namely, after the voltage generated by the organic thin film transparent solar cell 100 is controlled by the DC controller, the generated voltage is supplied to the purple LED module 20, or stored in the secondary lithium-ion battery.

### (Configuration of Transparent UV Cut Film)

As shown in FIG. 2, the transparent UV cut film 104 is formed just outside the organic thin film transparent solar cell 100 as seen from the purple LED module 20. The transparent UV cut film 104 absorbs and eliminates UV lights after being absorbed but not fully absorbed by the organic thin film transparent solar cell 100 to generate photovoltaic power. Thereby, the transparent UV cut film 104 suppresses a bad influence of emitting UV lights toward a lamp cover 105 or a human body existing in front of the transparent UV cut film 104, by transmitting the white light energy 68 as it is not containing UV lights.

Note that in this embodiment, the transparent UV cut film 104 is employed. However, any other material may be used as long as it is transparent and absorbs and eliminates UV lights. Further, if the organic thin film transparent solar cell 100 absorbs the UV lights to some extent and there is little influence of emitting UV lights toward the lamp cover 105 or the human body existing outside the organic thin film transparent solar cell 100, it is not necessary to form the transparent UV cut film 104.

### First Embodiment

Hereinafter, a self-generated lighting fixture according to a first embodiment of the present invention will be described.

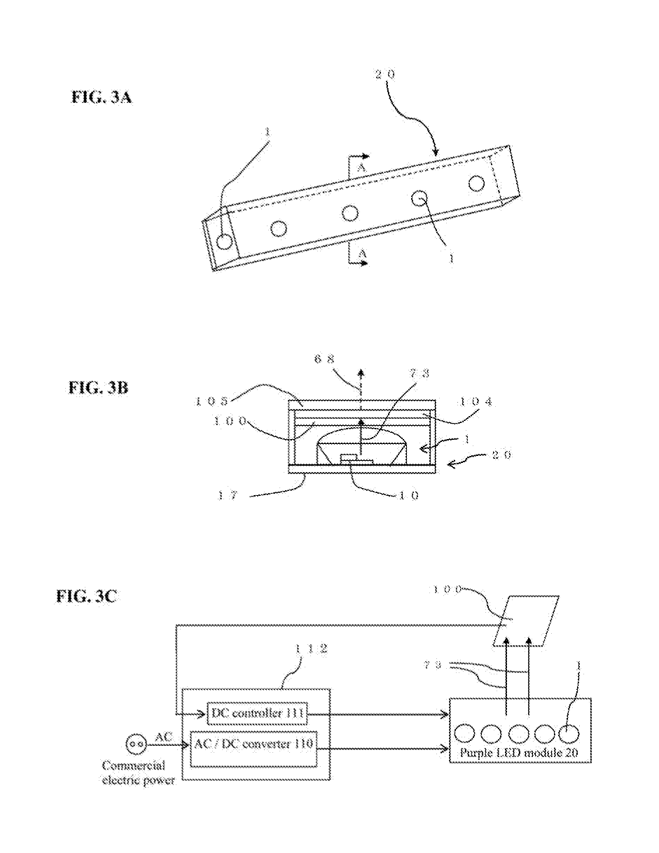

FIG. 3A is a schematic perspective view of a purple LED module including a frame of a self-generated lighting fixture according to a first embodiment of the present invention. Further, FIG. 3B is a cross-sectional view taken along the line A-A of FIG. 3A, and FIG. 3C is a schematic view showing a configuration example of an electric circuit of the self-generated lighting fixture according to the first embodiment of the present invention.

The purple LED module 20 is formed by connecting a plurality of surface mount-type purple LED packages 1.

The term “connecting” means a state in which purple LED packages 1 are arranged to be continuous with each other and are electrically connected. In this case, each purple LED package 1 emits and radiates UV light energy 73 upon receiving supply of electric power converted from commercial electric power (AC) to DC by an AC/DC converter 110. The organic thin film transparent solar cell 100 absorbs the UV light energy 73 emitted and radiated from each purple LED package 1 connected to a plurality of purple LED modules 20, and self-generate photovoltaic power by the photovoltaic effect.

Note that in FIG. 3B, the organic thin film transparent solar cell 100 is formed separately from the purple LED package 1, but the organic thin film transparent solar cell 100 is functionally the same as the organic thin film transparent solar cell 100 shown in FIG. 1B. Namely, the organic thin film transparent solar cell 100 may be anything as long as it absorbs the light energy radiated from the purple LED element 10 to generate electricity. Therefore, the organic thin film transparent solar cell 100 may be provided as a constituent element of the purple LED package 1, or may be provided as a constituent element of the purple LED module 20.

The transparent UV cut film 104 is formed just outside the organic thin film transparent solar cell 100 as seen from the surface mount-type purple LED package 1. The transparent UV cut film 104 absorbs and eliminates UV lights transmitted through the organic thin film transparent solar cell 100. The transparent UV cut film 104 absorbs and eliminates the remaining UV light after being absorbed by the organic thin film transparent solar cell 100 to generate photovoltaic power, and transmits the white light energy 68 as it is, not containing UV light. Thereby, the transparent UV cut film 104 suppresses a bad influence of emitting UV lights toward the lamp cover 105 or the human body existing in front of the transparent UV cut film 104.

Note that in FIG. 3B, the transparent UV cut film 104 is formed separately from the purple LED package 1, but functionally, it is the same as the transparent UV cut film 104 shown in FIG. 1B. Namely, the transparent UV cut film 104 may be anything as long as it can absorb and eliminate UV lights radiated from the purple LED element 10. Therefore, the transparent UV cut film 104 may be provided as a constituent element of the purple LED package 1, or may be provided as a constituent element of the purple LED module 20.

The lamp cover 105 is disposed on the opposite side (the side from which light is emitted) of the LED substrate 17, as seen from the purple LED package 1. The lamp cover 105 is formed so as to surround and cover the purple LED module 20 in a square shape. The transparent UV cut film 104 is formed on an inner surface of the lamp cover 105, and the organic thin film transparent solar cell 100 is formed on an inner surface of the transparent UV cut film 104. Therefore, the organic thin film transparent solar cell 100, the transparent UV cut film 104, and the lamp cover 105 are stacked in this order, as seen from the purple LED package 1.

The organic thin film transparent solar cell 100 absorbs the UV light energy 73 radiated from the purple LED module 20 to generate electricity by the photovoltaic effect. The photovoltaic power generated by the organic thin film transparent solar cell 100 is supplied to the purple LED module 20 via a DC controller 111.

### (Electric Circuit)

The power control unit 112 controls the electric power to be supplied to the purple LED module 20 (purple LED package 1) which is the light source, and includes commercial electric power as one of the electric powers to be controlled, and has an AC/DC converter 110 and a DC controller 111. The AC/DC converter 110 converts the commercial electric power (AC) to DC power upon receiving supply of the commercial electric power (AC). The DC power converted by the AC/DC converter 110 is supplied to the purple LED module 20. The DC power supplied to the purple LED module 20 is consumed to cause each purple LED package 1 to emit light (light up the purple LED module 20). The DC controller 111 controls so that the photovoltaic power generated by the organic thin film transparent solar cell 100 is compatible with the purple LED module 20. The electric power controlled by the DC controller 111 is supplied to the purple LED module 20. The electric power supplied from the DC controller 111 to the purple LED module 20 is consumed to cause each purple LED package 1 to emit light (light up the purple LED module 20) in the same manner as described above.

In the first embodiment of the present invention, each purple LED package 1 radiates UV light energy 73 by supplying the commercial electric power to the purple LED module 20 via the AC/DC converter 110. Then, the organic thin film transparent solar cell 100 absorbs the UV light energy radiated from each purple LED package 1, and generates the photovoltaic power by the photovoltaic effect. The photovoltaic power generated by the organic thin film transparent solar cell 100 is supplied to the purple LED module 20 via the DC controller 111. Thereby, the summed electric power of the commercial electric power and the electric power generated by the organic thin film transparent solar cell 100 is supplied to the purple LED module 20, and upon receiving the summed electric power, the purple LED module 20 radiates UV light energy 73. Therefore, the purple LED module 20 can exhibit capability to emit and radiate light energy that far exceeds an emission radiation power of the commercial electric power. Namely, in each purple LED package 1 of the purple LED module 20, the commercial electric power consumed for radiating UV light energy 73 may be a minimum necessary electric power, and it is possible to light up the purple LED module 20 with a power exceeding the emission radiation power of the commercial electric power only, due to summed power of the photovoltaic power generated by the organic thin film transparent solar cell 100 by absorption of the UV light energy 73 radiated by supplying minimum necessary electric power, and the commercial electric power.

Note that in the first embodiment, the purple LED package is used as the LED package, but the LED package is not limited thereto, and a near-UV light LED package, a blue LED package, a near-infrared LED package, or the like may also be used. Further, in the first embodiment, the organic thin film transparent solar cell is used as the transparent solar cell, but the transparent solar cell is not limited thereto, and transparent solar cells such as organic transparent solar cells including dye sensitized transparent solar cells, transparent innovative solar cells, transparent compound-based solar cells, transparent thin-film solar cells, etc., can be widely used.

### Second Embodiment

Next, a self-generated lighting fixture according to a second embodiment of the present invention will be described.

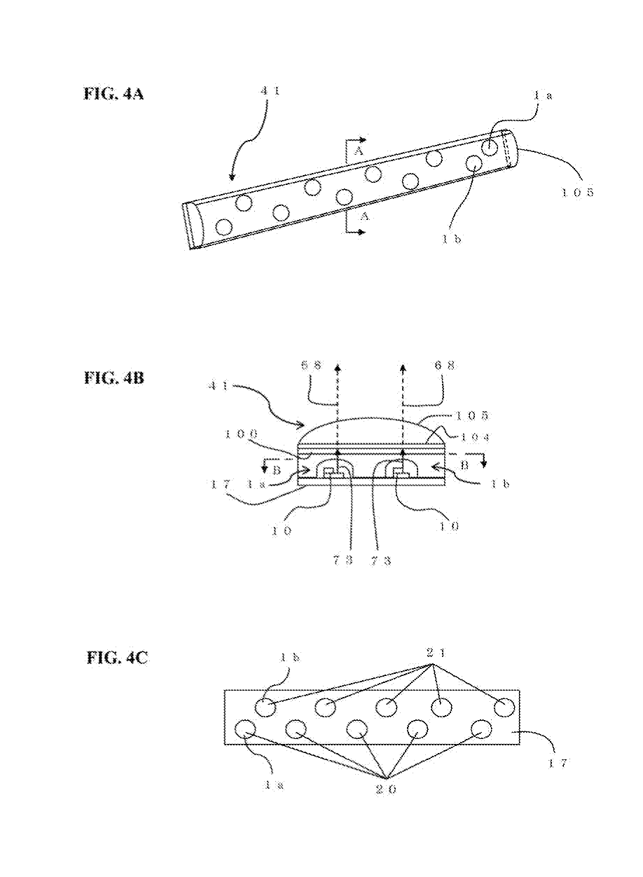

FIG. 4A is a perspective view including a frame of the self-generated lighting fixture according to a second embodiment of the present invention. Further, FIG. 4B is a cross-sectional view taken along the line A-A of FIG. 4A, FIG. 4C is a cross-sectional view taken along the line B-B of FIG. 4B, and FIG. 4D is a schematic view showing a configuration example of an electric circuit of the self-generated lighting fixture according to the second embodiment of the present invention. Note that in the second embodiment, elements that are different from those of the first embodiment will be mainly described, elements that are substantially the same as the elements described in the first embodiment will be given the same reference numerals, and description thereof will be omitted as much as possible.

The self-generated lighting fixture according to the second embodiment of the present invention includes an LED module unit 41 constituting an LED lighting fixture. The LED module unit 41 includes two LED modules (light sources) provided independently of each other, namely, the purple LED module 20 and the purple LED module 21. The purple LED module 20 is formed by connecting a plurality of surface mount-type purple LED packages 1a. Each purple LED package 1a emits and radiates the UV light energy 73 upon receiving supply of the commercial electric power. The purple LED module 21 is formed by connecting a plurality of surface mount-type purple LED packages 1b. Each purple LED package 1b emits and radiates the UV light energy 73 not upon receiving supply of the commercial electric power, but upon receiving the photovoltaic power from the organic thin film transparent solar cell 100.

The purple LED package 1a of the purple LED module 20 and the purple LED package 1b of the purple LED module 21, are mounted on a common LED substrate 17 but are not connected to each other. The purple LED module 21 (purple LED package 1b) self-radiates the UV light energy 73 independently of the purple LED module 20, upon receiving supply of the electric power from the power control unit 112, the electric power being generated by the organic thin film transparent solar cell 100, and supplies the radiated UV light energy 73 to the organic thin film transparent solar cell 100. Further, the purple LED module 21 radiates the UV light energy 73 by the electric power generated by the organic thin film transparent solar cell 100, without requiring the commercial electric power. The purple LED package 1a and the purple LED package 1b are arranged in two rows in a zigzag manner on the LED substrate 17, but this arrangement can be changed as necessary.

The organic thin film transparent solar cell 100 absorbs the UV light energy 73 radiated from each purple LED package 1a of the purple LED module 20 and the UV light energy 73 radiated from each purple LED package 1b of the purple LED module 21 respectively, and self-generates the photovoltaic power by the photovoltaic effect.

The transparent UV cut film 104 is formed just outside the organic thin film transparent solar cell 100 as seen from the purple LED packages 1a and 1b. The transparent UV cut film 104 absorbs and eliminates the UV lights that have not been absorbed by the organic thin film transparent solar cell 100 but have passed through it. The transparent UV cut film 104 absorbs and eliminates the remaining UV light after being absorbed by the organic thin film transparent solar cell 100 to generate photovoltaic power, and transmits the white light energy 68 as it is not containing the UV light. Thereby, the transparent UV cut film 104 suppresses the bad influence of emitting the UV lights toward the lamp cover 105 or the human body existing in front of the transparent UV cut film 104.

The lamp cover 105 is formed so as to surround and cover the purple LED module 20 and the purple LED module 21. The lamp cover 105 is made of glass or resin. The transparent UV cut film 104 is formed on the inner surface of the lamp cover 105, and the organic thin film transparent solar cell 100 is formed on the inner surface of the transparent UV cut film 104. Therefore, the organic thin film transparent solar cell 100, the transparent UV cut film 104, and the lamp cover 105 are stacked in this order, as seen from purple LED packages 1a and 1b.

### (Electric Circuit)

The power control unit 112 controls the electric power to be supplied to the purple LED module 20 (purple LED package 1a) and the purple LED module 21 (purple LED package 1b) which are light sources, and includes commercial electric power as one of the electric powers to be controlled, and has the AC/DC converter 110 and the DC controller 111. The AC/DC converter 110 converts the commercial electric power (AC) to DC power, upon receiving the commercial electric power (AC). The DC power converted by the AC/DC converter 110 is supplied to the purple LED module 20. The DC power supplied to the purple LED module 20 is consumed to cause each purple LED package 1a to emit light (light up the purple LED module 20). The DC controller 111 controls so that the photovoltaic power generated by the organic thin film transparent solar cell 100 is compatible with the purple LED module 21. The electric power controlled by the DC controller 111 is supplied to the purple LED module 21. The electric power supplied from the DC controller 111 to the purple LED module 21 is consumed to cause each purple LED package 1b to emit light (light up the purple LED module 21).

In the second embodiment of the present invention, each purple LED package 1a radiates UV light energy 73 by supplying the commercial electric power to the purple LED module 20 via the AC/DC converter 110. Then, the organic thin film transparent solar cell 100 absorbs the UV light energy 73 radiated from each purple LED package 1a, and generates the photovoltaic power by the photovoltaic effect. The photovoltaic power generated by the organic thin film transparent solar cell 100 is supplied to the purple LED module 21 via the DC controller 111. Thereby, each purple LED package 1b radiates UV light energy 73, and the organic thin film transparent solar cell 100 absorbs the UV light energy 73 and generates the photovoltaic power. Then, the organic thin film transparent solar cell 100 absorbs the UV light energy 73 radiated from each purple LED package 1b, and generates the photovoltaic power by the photovoltaic effect. Then, this photovoltaic power is again supplied to the purple LED module 21 via the DC controller 111. As a result, the organic thin film transparent solar cell 100 absorbs a summed light energy (UV light energy 73) from both the purple LED package 1a of each purple LED module 20 and the purple LED package 1b of each purple LED module 21, to generate electricity. Thereby, the LED module unit 41 can exhibit a power to radiate light energy that far exceeds the emission radiation power of the commercial electric power. Namely, in each purple LED package 1 of the purple LED module 20, the commercial electric power consumed for radiating UV light energy 73 may be a minimum necessary electric power, and it is possible to light up the purple LED module 41 with a power exceeding the emission radiation power of the commercial electric power only, due to summed power of the photovoltaic power generated by the organic thin film transparent solar cell 100 by absorption of the UV light energy 73 radiated by supplying minimum necessary electric power, and the commercial electric power, thereby further increasing the power generation capability.

Note that in the second embodiment, the purple LED package is used as the LED package, but the LED package is not limited thereto, and the near-UV light LED package, the blue LED package, the near-infrared LED package, or the like may also be used. Further, in the second embodiment, the organic thin film transparent solar cell is used as the transparent solar cell, but the transparent solar cell is not limited thereto, and transparent solar cells such as organic transparent solar cells including dye sensitized transparent solar cells, transparent innovative solar cells, transparent compound-based solar cells, transparent thin-film solar cells, etc., can be widely used.

### Third Embodiment

Next, a self-generated lighting fixture according to a third embodiment of the present invention will be described.

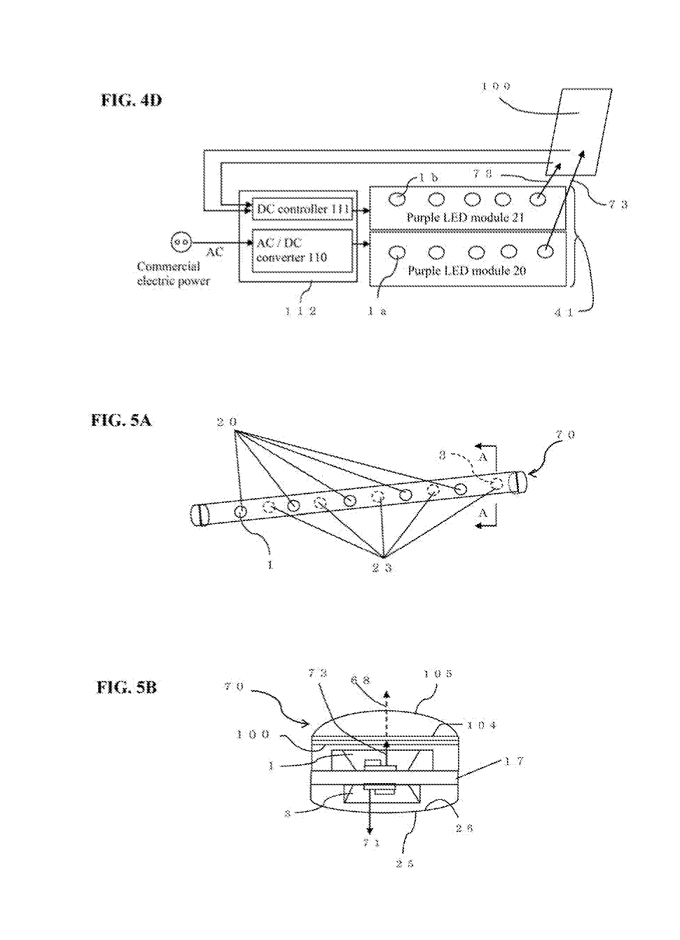

FIG. 5A is a perspective view including a frame of a self-generated lighting fixture according to a third embodiment of the present invention, FIG. 5B is a cross-sectional view taken along the line A-A of FIG. 5A, and FIG. 5C is a schematic view showing a configuration example of an electric circuit of the self-generated lighting fixture according to the third embodiment of the present invention. Note that in this third embodiment, elements that are different from those of the first embodiment will be mainly described, elements that are substantially the same as the elements described in the first embodiment will be given the same reference numerals, and description thereof will be omitted as much as possible.

The self-generated lighting fixture according to a third embodiment of the present invention includes a long LED lamp 70. The LED lamp 70 includes: an LED substrate 17 serving as a mounting board; a purple LED module 20 in which a plurality of surface mount-type purple LED packages 1 are connected in a longitudinal direction; a UV light LED module 23 in which a plurality of UV light LED packages 3 are connected in a longitudinal direction; a titanium oxide apatite layer 25 exhibiting photocatalytic function; a back side lamp cover 26; the organic thin film transparent solar cell 100; the transparent UV cut film 104; and the lamp cover 105.

Each purple LED package 1 of the purple LED module 20 emits and radiates the UV light energy 73 upon receiving supply of the commercial electric power, and supplies the UV light energy 73 to the organic thin film transparent solar cell 100.

Each UV light LED package 3 of the ultraviolet LED module 23 is mounted on the LED substrate 17 common to the purple LED package 1 of the purple LED module 20, but its mounting surface is opposite to the purple LED package 1 upside down. Namely, the purple LED package 1 is mounted on one main surface of the LED substrate 17, and the UV light LED package 3 is mounted on the other main surface of the LED substrate 17. Therefore, the UV light LED package 3 emits light to the side opposite to the purple LED package 1. Further, the UV light LED package 3 is not connected to the purple LED package 1. Each purple LED package 3 radiates the UV light energy 73 not upon receiving supply of the commercial electric power but upon receiving the photovoltaic power from the organic thin film transparent solar cell 100.

The organic thin film transparent solar cell 100 absorbs the UV light energy 73 emitted and radiated from each purple LED package 1 of the purple LED module 20, and self-generates the photovoltaic power by the photovoltaic effect. The photovoltaic power generated by the organic thin film transparent solar cell 100 is supplied to the ultraviolet LED module 23, and consumed to cause each UV light LED package 3 to emit light.

The transparent UV cut film 104 is formed just outside the organic thin film transparent solar cell 100 as seen from the purple LED element 1. The transparent UV cut film 104 absorbs the UV lights which are transmitted through the organic thin film transparent solar cell 100 and which cannot be completely absorbed by the organic thin film transparent solar cell 100. The transparent UV cut film 104 absorbs and eliminates the remaining UV light after being absorbed by the organic thin film transparent solar cell 100 to generate the photovoltaic power, and transmits the white light energy 68 as it is not containing the UV light. Thereby, the transparent UV cut film 104 suppresses the bad influence of emitting the UV lights toward the lamp cover 105 or the human body existing in front of the transparent UV cut film 104.

The ultraviolet LED module 23 is installed on the opposite side (back side) of the side (front side) on which the purple LED module 20 is installed with the LED substrate 17 interposed therebetween. Therefore, the ultraviolet LED module 23 emits and radiates the UV light energy 71 in a direction opposite to a direction in which the purple LED module 20 emits and radiates the UV light energy 71. Thereby, it is possible to suppress the bad influence of radiating the UV light energy 71 toward human beings, animals and plants existing on the side where the purple LED module 20 emits and radiates the UV light energy 71.

The lamp cover 105 is formed so as to surround and cover the purple LED module 20 (purple LED module 1). The lamp cover 105 is made of glass or resin. The transparent UV cut film 104 is formed on the inner surface of the lamp cover 105, and the organic thin film transparent solar cell 100 is formed on the inner surface of the transparent UV cut film 104. Therefore, the organic thin film transparent solar cell 100, the transparent UV cut film 104, and the lamp cover 105 are stacked in this order, as seen from the purple LED package 1.

The back side lamp cover 26 is a resin or glass lamp so as to surround and cover the ultraviolet LED module 23 (UV light LED package 3). The titanium oxide apatite layer 25 is formed on the outer surface of the back side lamp cover 26. The titanium oxide apatite layer 25 is formed by coating or sticking titanium oxide apatite to the outer surface of the back side lamp cover 26, the titanium oxide apatite being formed by ion exchange of titanium oxide in an apatite crystal structure. The titanium oxide apatite layer 25 exhibits a photocatalytic function such as deodorant effect, antibacterial effect, and bactericidal effect, by being excited upon receiving the UV light energy 71 which is emitted and radiated from each UV light LED package 3 of the ultraviolet LED module 23.

Note that in this third embodiment, the long LED lamp 70 is employed, but the LED lamp is not limited thereto, and surcline type, down light type, or projector type may also be employed.

### (Electric Circuit)

The power control unit 112 controls the electric power to be supplied to the purple LED module 20 (purple LED package 1a) and the purple LED module 23 (purple LED package 3) which are light sources, and includes the commercial electric power as one of the electric powers to be controlled, and includes the AC/DC converter 110 and the DC controller 111. The AC/DC converter 110 converts the commercial electric power (AC) to DC power upon receiving supply of the commercial electric power (AC). The DC power converted by the AC/DC converter 110 is supplied to the purple LED module 20. The DC power supplied to the purple LED module 20 is consumed to cause each purple LED package 1 to emit light (light up the purple LED module 20). The DC controller 111 controls so that the photovoltaic power generated by the organic thin film transparent solar cell 100 is compatible with the purple LED module 23. The electric power controlled by the DC controller 111 is supplied to the purple LED module 23. The electric power supplied from the DC controller 111 to the purple LED module 23 is consumed to cause each purple LED package 3 to emit light (light up the purple LED module 23).

In the third embodiment of the present invention, each purple LED package 1 radiates the UV light energy 73 by supplying the commercial electric power to the purple LED module 20 via the AC/DC converter 110. Then, the organic thin film transparent solar cell 100 absorbs the UV light energy 73 radiated from each purple LED package 1, and generates the photovoltaic power by the photovoltaic effect. The photovoltaic power generated by the organic thin film transparent solar cell 100 is supplied to the UV light LED module 23 via the DC controller 111. Thereby, each UV light LED package 3 radiates the UV light energy 71. As a result, it becomes possible to emit and radiate the light energy to the front surface side and the back surface side of the LED lamp 70 respectively, utilizing the photovoltaic power generated by the organic thin film transparent solar cell 100. Further, it is possible to exhibit photocatalytic functions such as deodorant effect, antibacterial effect, and bactericidal effect, by exciting the titanium oxide apatite layer 25 with the UV light emitted and radiated from each UV light LED package 3 of the UV light LED module 23.

Note that in the third embodiment, the purple LED package and the UV light LED package are used as the LED package, but the LED package is not limited thereto, and the near-UV light LED package, the blue LED package, the near-infrared LED package, or the like may also be used, instead of the purple LED package or instead of the UV light LED package. Further, in the third embodiment, LED packages with different emission wavelengths are mounted on the front and back surfaces of the LED substrate 17, but the mount of the LED packages is not limited thereto, and LED packages having the same emission wavelengths may be mounted on the front and back surfaces of the LED substrate 17. Further, in the third embodiment, the organic thin film transparent solar cell is used as the transparent solar cell, but the transparent sola cell is not limited thereto, and transparent solar cells such as organic transparent solar cells including dye sensitized transparent solar cells, transparent innovative solar cells, transparent compound-based solar cells, transparent thin-film solar cells, etc., can be widely used.

### Fourth Embodiment

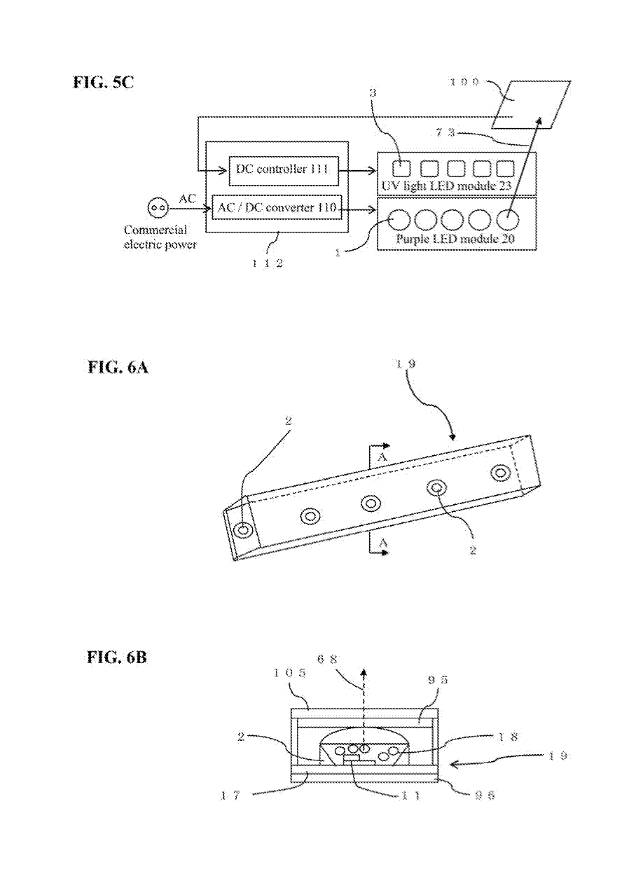

Next, a self-generated lighting fixture according to a fourth embodiment of the present invention will be described. FIG. 6A is a perspective view including the frame of the self-generated lighting fixture according to the fourth embodiment of the present invention, FIG. 6B is a cross-sectional view taken along the line A-A of FIG. 6A, and FIG. 6C is a schematic view showing a configuration example of an electric circuit of the self-generated lighting fixture according to the fourth embodiment of the present invention. Note that in the fourth embodiment, elements that are different from those of the first embodiment will be mainly described, elements that are substantially the same as the elements described in the first embodiment will be given the same reference numerals, and description thereof will be omitted as much as possible.

The self-generated lighting fixture according to the fourth embodiment of the present invention includes: a long blue LED module 19, a dye sensitized transparent solar cell 95, the lamp cover 105, and an external transparent solar cell 96.

The blue LED module 19 is formed by connecting a plurality of surface mount-type blue LED packages 2. Each blue LED package 2 is mounted on the LED substrate 17 at a predetermined interval, and radiates the white light energy 68 upon receiving the electric power from the power storage device 121 (lithium ion storage battery 120). The blue LED package 2 has a blue LED element 11. The blue LED element 11 is sealed by a resin-based sealing material 18 containing a yellow phosphor.

The dye sensitized transparent solar cell 95 absorbs the white light energy 68 radiated from each blue LED package 2 of the blue LED module 19, and self-generates the photovoltaic power by the photovoltaic effect.

The external transparent solar cell 96 absorbs the light energy of street lights (including security lights) and sunlight, and self-generates the photovoltaic power by the photovoltaic effect. The external transparent solar cell 96 is formed in a planar shape on the back surface (outer surface) of the LED substrate 17 which is a back surface side radiating portion of the blue LED module 19. The external transparent solar cell 96 can be constituted of the organic thin film transparent solar cell, the dye sensitized transparent solar cell, or other transparent solar cell.

The lamp cover 105 is formed so as to surround and cover the blue LED module 19 in a square shape. The lamp cover 105 is made of glass or resin. The dye sensitized transparent solar cell 95 is formed in a planar shape on the inner surface of the lamp cover 105 so as to face each blue LED package 2. By disposing the dye sensitized transparent solar cell 95 immediately in the vicinity of the blue LED package 2, the dye sensitized transparent solar cell 95 absorbs the white light energy 68 radiated from the blue LED package 2 with little attenuation, and can generate the electric power with high photovoltaic power.

### (Electric Circuit)

The power control unit 112 controls the electric power to be supplied to the blue LED module 19 (blue LED package 2) which is a light source, and includes the commercial electric power as one of the electric powers to be controlled, and has the AC/DC converter 110 and the DC controller 111. The power control unit 112 captures the commercial electric power and the electric power generated by the transparent solar cells (95, 96), and supplies the captured electric power to the power storage device 121. The AC/DC converter 110 converts the commercial electric power (AC) to DC power upon receiving supply of the commercial electric power (AC). The DC power converted by the AC/DC converter 110 is stored in the lithium ion storage battery 120 of the power storage device 121. The DC controller 111 controls so that the photovoltaic power generated by the dye sensitized transparent solar cell 95 and the external transparent solar cell 96 is compatible with the blue LED module 19. The electric power controlled by the DC controller 111 is stored in the lithium ion storage battery 120 of the power storage device 121.

The power storage device 121 includes a lithium ion storage battery 120 stores electricity upon receiving supply of the electric power from the power control unit 112, and supplies the electric power stored in the lithium ion storage battery 120 to the blue LED package 2 of the blue LED module 19. The lithium ion storage battery 120 stores electricity supplied from the AC/DC converter 110 and the DC controller 111 of the power control unit 112. The electric power stored in the lithium ion storage battery 120 is supplied to the blue LED module 19. The electric power supplied to the blue LED module 19 is consumed to cause each blue LED package 2 to emit light (light up the blue LED module 19).

Further, the power storage device 121 has a detecting function of detecting stop of supply of the electric power from the power control unit, and/or power failure, in addition to on (energizing)/off (cutoff) function of a power switch. When the stop of supply of the electric power from the power control unit 112 and/or the power failure is detected by the detecting function, the power storage device 121 has an endless function of always turning on the blue LED package 2 by continuously supplying the electric power stored in the lithium ion storage battery 120 to blue LED package 2 of the blue LED module 19 and resuming supply of the electric power to the blue LED package 2 of the blue LED module 19 upon receiving supply of the electric power generated by the dye sensitized transparent solar cell 95 by absorption of the white light energy 68 radiated from the blue LED package 2 during on-state. Note that the power switch is a switch for turning on the self-generated lighting fixture in the on-state and turning off the self-generated lighting fixture in the off state. Further, “always on-state” means to keep the light source for illumination on, before and after detecting with the detecting function.

Further, when a charged amount of the lithium ion battery 120 reaches a fully charged state upon receiving supply of the electric power from the power control unit 112, the power storage device 121, by itself, has an overcharge prevention function of stopping supply of the electric power from the power control unit 112. Further, when supply of the electric power from the power control unit 112 is stopped by the overcharge prevention function and thereafter the electric power is consumed from the fully charged state to become storable, the power storage device 121 has a function of storing electricity upon receiving supply of the electric power from the power control unit 112, the electric power being generated by the dye sensitized transparent solar cell 95 and the external transparent solar cell 96, and when the storage amount of the lithium ion storage battery 120 is decreased to a preset remaining charged amount during this storage, the power storage device 121 has a function of resuming supply of the commercial electric power to the blue LED package 2 of the blue LED module 19 upon receiving supply of the commercial electric power from the power control unit 112. For example, the remaining charged amount may be set within a range of 30% or more and 50% or less when the fully charged amount in the fully charged state is taken as 100%. Note that the reason why a range of 30% or more and 50% or less is set for the setting of the remaining charged amount is because, there is a possibility that a proper value of the remaining power storage amount may be changed depending on an installing location and an infrastructure environment of the self-generated lighting fixture. Specifically, the time required for recovery after power failure tends to be relatively short in urban areas and relatively long in mountainous areas, and in this case, it is better to set the remaining charged amount to about 30% in the urban areas, and it is better to set the remaining charged amount to about 50% in the mountainous areas. Therefore, it is desirable to appropriately set the remaining charged amount according to a location where the blue LED module 19 is used.

In the fourth embodiment of the present invention, each blue LED package 2 radiates white light energy 68, by supplying the commercial electric power stored in the lithium ion storage battery 120, to the blue LED module 19 by the power storage device 121 via the AC/DC converter 110. Then, the dye sensitized transparent solar cell 95 absorbs the white light energy 68 radiated from each blue LED package 2, and generates the photovoltaic power by the photovoltaic effect. Meanwhile, the external transparent solar cell 96 absorbs the light energy of street lights or sunlight, and generates the photovoltaic power by the photovoltaic effect. The photovoltaic power generated by the dye sensitized transparent solar cell 95 and the external transparent solar cell 96 in this manner is captured into the power storage device 121 via the DC controller 111, stored in the lithium ion storage battery 120, and thereafter supplied again to the blue LED module 19 by the power storage device 121. As a result, it is possible to emit and radiate the white light energy 68 from the blue LED package 2 of the blue LED module 19, utilizing the photovoltaic power generated by the dye sensitized transparent solar cell 95 and the external transparent solar cell 96.

Further, when the stop of supply of the electric power from the power control unit 112 or the power failure is detected due to some abnormality while the power supply switch is turned on, the power storage device 121 continuously supplies the electric power stored in the lithium ion storage battery 120, to the blue LED package 2 of the blue LED module 19. Thereby, it is possible to maintain the blue LED package 2 in the on-state (lighting state of the blue LED module 19). Further, the power storage device 121 stores electricity in the lithium ion storage battery 120 upon receiving the photovoltaic power from the power control unit 112, the photovoltaic power being generated by the dye sensitized transparent solar cell 95 using the white light energy 68 radiated from the on-state blue LED package 2 and the photovoltaic power being generated by the external transparent solar cell 96 using the light energy of the street lights or the sunlight, and resumes supply of the electric power to the blue LED package 2 therefrom. Thereby, it is possible to maintain the blue LED package 2 in the on-state while minimizing the consumption of commercial electric power.

Further, when supply of the electric power from the power control unit 112 is stopped by the overcharge prevention function and thereafter the electric power is consumed from the fully charged state to become storable, the power storage device 121 stores electricity in the lithium ion storage battery 120 upon receiving supply of the electric power from the power control unit 112, the electric power being generated by the dye sensitized transparent solar cell 95 and the external transparent solar cell 96, and when the storage amount of the lithium ion storage battery 120 is decreased to a preset remaining charged amount during the storage, the power storage device 121 resumes supply of the commercial electric power to the blue LED package 2 of the blue LED module 19 upon receiving supply of the commercial electric power from the power control unit 112. Thereby, it is possible to maintain the blue LED package 2 in the on-state, while supplementing a shortage of the charged amount by supply of the commercial electric power, the shortage being caused by supply of the electric power generated by the dye sensitized transparent solar cell 95 and the external transparent solar cell 96.

Even if the power failure occurs while being in the lighting state of the blue LED module 19 (blue LED package 2), the blue LED package 2 emits the white light energy 68 upon receiving supply of the electric power continuously from the lithium ion storage battery 120, and the dye sensitized transparent solar cell 95 repeats self-power generation by absorption of the white light energy 68, and stores electricity in the lithium ion storage battery 120. Thereby, it is possible to achieve a longer life of the discharge capacity time of the lithium ion storage battery 120. Further, the blue LED package 2 continues to emit the white light energy 68 until the charged amount in the lithium ion storage battery 120 becomes zero as long as the power switch is not turned off (cut off). Therefore, it is possible to realize the self-generated lighting fixture having both a function as a lighting fixture responding to long-term emergency power failure and a power saving function during stop of the supply of the commercial electric power.

Note that in the fourth embodiment, the blue LED package is used as the LED package, but the LED package is not limited thereto, and the purple LED package, the near-UV light LED package, the near infrared LED package, or the like may also be used. Further, in the fourth embodiment, the dye sensitized transparent solar cell is used as the transparent solar cell, but the transparent solar cell is not limited thereto, and transparent solar cells such as organic transparent solar cells including organic thin film transparent solar cells, transparent innovative solar cells, transparent compound-based solar cells, transparent thin-film solar cells, etc., can be widely used. This also applies to the external transparent solar cell 96. Further, in the fourth embodiment, the blue LED module formed in a long shape is used, but the blue LED module is not limited thereto, and for example, an LED module formed in a surcline type, square shape, round shape, or projector type may also be used. Further, in the fourth embodiment, the lamp cover is formed into a square shape, but the shape of the lamp cover is not limited thereto, and it may have any shape such as an elliptical shape, a round shape, and the like. Further, in the fourth embodiment, the lithium ion storage battery is used as an example of the storage battery (secondary battery), but other storage batteries (for example, a lead storage battery, a nickel storage battery, etc.) may also be used.

### Fifth Embodiment

Next, a self-generated lighting fixture according to a fifth embodiment of the present invention will be described.

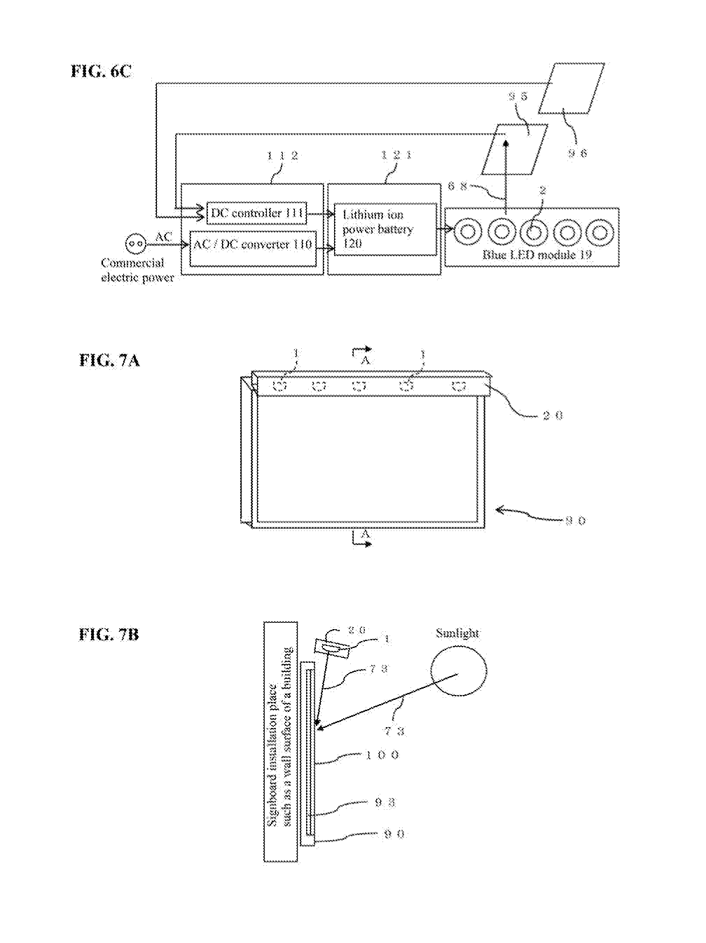

FIG. 7A is a perspective view including a frame of a self-generated lighting fixture according to a fifth embodiment of the present invention, FIG. 7B is a cross-sectional view taken along the line A-A of FIG. 7A, and FIG. 7C is a schematic view showing a configuration example of an electric circuit of the self-generated lighting fixture according to the fifth embodiment of the present invention. Note that in the fifth embodiment, elements that are different from those of the first embodiment will be mainly described, elements that are substantially the same as the elements described in the first embodiment will be given the same reference numerals, and description thereof will be omitted as much as possible.

The self-generated lighting fixture according to the fifth embodiment of the present invention includes: the long purple LED module 20; an external light signboard frame 90, a picture display panel 93, and the organic thin film transparent solar cell 100.

The purple LED module 20 is formed by connecting a plurality of surface mount-type purple LED packages 1. Each purple LED package 1 is disposed in the longitudinal direction of the purple LED module 20 at a predetermined interval, and radiates the UV light energy 73 upon receiving supply of the electric power from the power storage device 121 (lithium ion storage battery 120). The purple LED module 20 is disposed on the signboard to be irradiated (including the external light signboard frame 90) or the surrounding wall surface of the signboard in such a manner as being inclined at a predetermined angle, so that the picture display panel 93 is irradiated from an oblique direction (diagonally upward in the figure) with the UV light energy 73 radiated from the purple LED package 1. An inclination angle of the purple LED module 20 can be represented by an angle at which a principal ray of the UV light energy 73 radiated from the purple LED package 1 is incident on the organic thin film transparent solar cell 100, and for example, it is set in a range of 10 degrees or more and 60 degrees or less.

The external light signboard frame 90 is a frame installed at a signboard installation place such as a wall surface of a building.

The picture display panel 93 is integrally formed with the external light signboard frame 90 as a part of the external light signboard frame 90, or is formed separately from the external light signboard frame 90. The picture display panel 93 has a display surface (bulletin board) on which a picture to be displayed on the external signboard is displayed. When the picture display panel 93 is integrally formed with the external light signboard frame 90, the picture to be displayed is pasted directly on the external light signboard frame 90 by painting, cutting characters or the like. The picture display panel 93 is an irradiation target surface which is irradiated with the UV light energy 73 from the purple LED package 1, and is disposed outward.

The organic thin film transparent solar cell 100 is formed on the display surface of the picture display panel 93 in a planar shape so as to cover the display surface. An inner surface of the organic thin film transparent solar cell 100 is close to and faces the display surface of the picture display panel 93. An outer surface of the organic thin film transparent solar cell 100 forms an outermost surface of the external light signboard. The display surface of the picture display panel 93 covered with the organic thin film transparent solar cell 100 is irradiated with the UV light energy 73 from the purple LED package 1 of the purple LED module 20. Therefore, the display surface of the picture display panel 93 becomes a surface to be irradiated with the UV light energy 73 from the purple LED package 1 of the purple LED module 20. Further, the display surface of the picture display panel 93 is also irradiated with the UV light energy 73 from the sunlight. Therefore, the organic thin film transparent solar cell 100 absorbs both the UV light energy 73 radiated from the purple LED package 1 of the purple LED module 20 and the UV light energy 73 from the sunlight, and generates the photovoltaic power by the photovoltaic effect.

### (Electric Circuit)

The power control unit 112 controls the electric power to be supplied to the purple LED module 20 (purple LED package 1) which is a light source, and includes the commercial electric power as one of the electric powers to be controlled, and has the AC/DC converter 110 and the DC controller 111. The AC/DC converter 110 converts the commercial electric power (AC) to DC power, upon receiving supply of commercial electric power (AC). The DC power converted by the AC/DC converter 110 is stored in the lithium ion storage battery 120 of the power storage device 121. The DC controller 111 controls so that the photovoltaic power generated by the organic thin film transparent solar cell 100 is compatible with the purple LED module 20. The electric power controlled by the DC controller 111 is stored in the lithium ion storage battery 120 of the power storage device 121.

The power storage device 121 includes a lithium ion storage battery 120 stores electricity upon receiving supply of the electric power from the power control unit 112, and supplies the electric power stored in the lithium ion storage battery 120 to the purple LED package 1 of the purple LED module 20. The lithium ion storage battery 120 stores electricity supplied from the AC/DC converter 110 and the DC controller 111 of the power control unit 112. The electric power stored in the lithium ion storage battery 120 is supplied to the purple LED module 20. The electric power supplied to the purple LED module 20 is consumed to cause each purple LED package 1 to emit light (light up the purple LED module 20).

Further, the power storage device 121 has a detecting function of detecting stop of supply of the electric power from the power control unit 112, and/or power failure, in addition to on (energizing)/off (cutoff) function of a power switch. Then, when the stop of supply of the electric power from the power control unit 112 and/or the power failure is detected by the detecting function, the power storage device 121 has an endless function of always turning on the purple LED package 1 by continuously supplying the electric power stored in the lithium ion storage battery 120 to the purple LED package 1 of the purple LED module 20 and resuming supply of the electric power to the purple LED package 1 of the purple LED module 20 upon receiving supply of the electric power from the power control unit 112, the electric power being generated by the organic thin film transparent solar cell 100 by absorption of the UV light energy 73 radiated from the purple LED package 1 during the on-state.

Further, when a charged amount of the lithium ion battery 120 reaches a fully charged state upon receiving supply of the electric power from the power control unit 112, the power storage device 121, by itself, has an overcharge prevention function of stopping supply of the electric power from the power control unit 112. Further, when supply of the electric power from the power control unit 112 is stopped by the overcharge prevention function and thereafter the electric power is consumed from the fully charged state to become storable, the power storage device 121 has a function of storing electricity upon receiving supply of the electric power generated by the organic thin film transparent solar cell 100 from the power control unit 112, and when the storage amount of the lithium ion storage battery 120 is decreased to a preset remaining charged amount during this storage, the power storage device 121 has a function of resuming supply of the commercial electric power to the purple LED package 1 of the purple LED module 20 upon receiving supply of the commercial electric power from the power control unit 112. Note that the setting of the remaining charged amount is the same as that in the fourth embodiment.

In the fifth embodiment of the present invention, each purple LED package 1 radiates the UV light energy 73, by supplying the commercial electric power stored in the lithium ion storage battery 120, to the purple LED module 20 by the power storage device 121 via the AC/DC converter 110. Then, the organic thin film transparent solar cell 100 absorbs the UV light energy 73 radiated from each purple LED package 1, and generates the photovoltaic power by the photovoltaic effect. Further, the organic thin film transparent solar cell 100 absorbs the UV light energy 73 from the sunlight, and generates the photovoltaic power by the photovoltaic effect. The photovoltaic power generated by the organic thin film transparent solar cell 100 in this manner is captured into the power storage device 121 via the DC controller 111, stored in the lithium ion storage battery 120, and thereafter supplied again to the purple LED module 20 by the power storage device 121. As a result, it is possible to radiate the UV light energy 73 from the purple LED package 1 of the purple LED module 20 and to irradiate the display surface of the picture display panel 93 with the UV light energy 73.

Further, when the stop of supply of the electric power from the power control unit 112 is detected due to some abnormality or power failure while the power supply switch is turned on, the power storage device 121 continuously supplies the electric power stored in the lithium ion storage battery 120, to the purple LED package 1 of the purple LED module 20. Thereby, it is possible to maintain the purple LED package 1 in the on-state (lighting state of the purple LED module 20). Further, the power storage device 121 stores electricity in the lithium ion storage battery 120 upon receiving the photovoltaic power from the power control unit 112, the photovoltaic power being generated by the organic thin film transparent solar cell 100 using the UV light energy 73 radiated from the purple LED package 1 during the on-state and the photovoltaic power being generated by the organic thin film transparent solar cell 100 using the light energy of the sunlight, and resumes supply of the electric power to the purple LED package 1 therefrom. Thereby, it is possible to maintain the purple LED package 1 in the on-state while minimizing the consumption of commercial electric power.

Further, when supply of the electric power from the power control unit 112 is stopped by the overcharge prevention function and thereafter the electric power is consumed from the fully charged state to become storable, the power storage device 121 stores electricity in the lithium ion storage battery 120 upon receiving supply of the electric power from the power control unit 112, the electric power being generated by the organic thin film transparent solar cell 100, and when the storage amount of the lithium ion storage battery 120 is decreased to a preset remaining charged amount during this storage, the power storage device 121 resumes supply of the commercial electric power to the purple LED package 1 of the purple LED module 20 upon receiving supply of the commercial electric power from the power control unit 112. Thereby, it is possible to maintain the purple LED package 1 in the on-state, while supplementing the shortage of the charged amount by supply of the commercial electric power, the shortage of the charged amount being caused by supply of the electric power generated by the organic thin film transparent solar cell 100.

As described above, even if the power failure occurs while being in the lighting state of the obliquely inclined purple LED module 20, the purple LED package 1 radiates the UV light energy 73 upon receiving supply of the electric power continuously from the lithium ion storage battery 120, and the organic thin film transparent solar cell 100 repeats power generation by absorption of the UV light energy 73 to self-generate electricity, and stores it in the lithium ion storage battery 120. Thereby, it is possible to achieve a longer life of the discharge capacity time of the lithium ion storage battery 120. Further, the purple LED package 1 continuously emits the UV light energy 73 until the charged amount in the lithium ion storage battery 120 becomes zero as long as the power switch is not turned off (cut off). Therefore, it is possible to realize the self-generated lighting fixture having both the function as a lighting fixture responding to long-term emergency power failure and the power saving function during stop of the supply of the commercial electric power. Further, in many cases, the external lighting fixtures assumed in the fifth embodiment are installed on the walls of buildings beside sidewalks in downtown areas. Therefore, if the self-generated lighting fixture of the fifth embodiment is applied to such an external lighting fixture, it is possible to give a sense of safety and security to the surroundings by illuminating an entrance of the building and the sidewalk brightly at the time of the power failure.

Note that in the fifth embodiment, the purple LED package is used as the LED package, but the LED package is not limited thereto, and the blue LED package, the near-UV light LED package, the near infrared LED package, or the like may also be used. Further, in the fifth embodiment, the organic thin film transparent solar cell is used as the transparent solar cell, but the transparent solar cell is not limited thereto, and transparent solar cells such as organic transparent solar cells including dye sensitized transparent solar cells, transparent innovative solar cells, transparent compound-based solar cells, transparent thin-film solar cells, etc., can be widely used. Further, in the fifth embodiment, the lithium ion storage battery is used as an example of the storage battery (secondary battery), but other storage batteries (for example, a lead storage battery, a nickel storage battery, etc.) may also be used. Further, in the fifth embodiment, the picture display panel is used as the panel having an irradiation target surface, but it may be a panel displaying things other than a picture, or a panel without a picture or the like.

### Sixth Embodiment

Next, a self-generated lighting fixture according to a sixth embodiment of the present invention will be described.

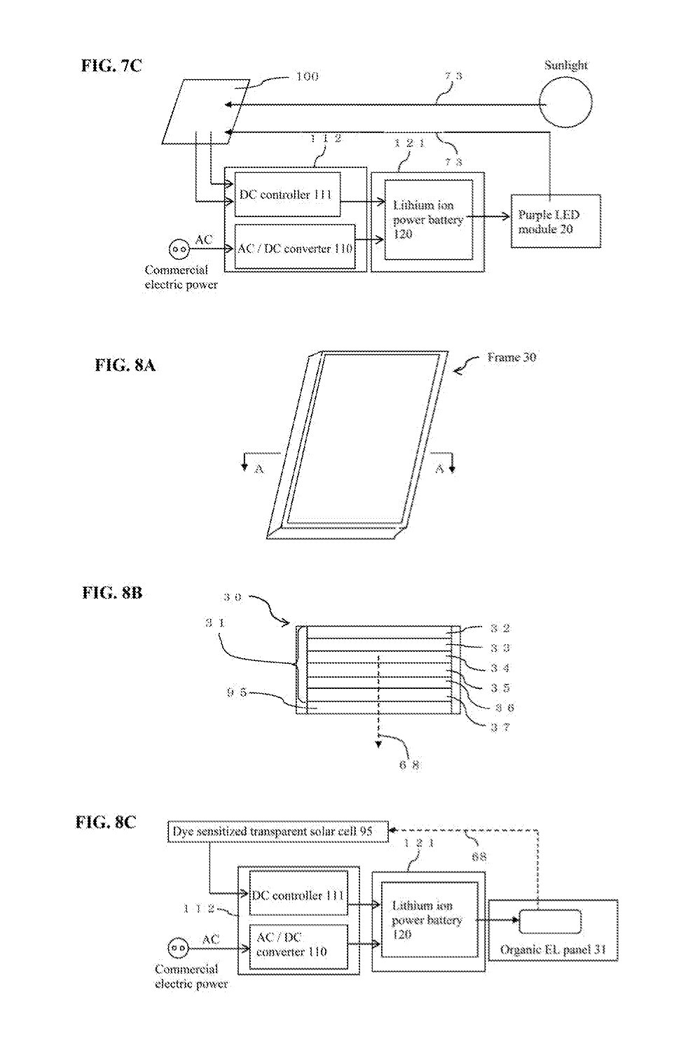

FIG. 8A is a perspective view including the frame of the self-generated lighting fixture according to the sixth embodiment of the present invention, FIG. 8B is a cross-sectional view taken along the line A-A of FIG. 8A, and FIG. 8C is a schematic view showing a configuration example of an electric circuit of the self-generated lighting fixture according to the sixth embodiment of the present invention. Note that in the sixth embodiment, elements that are different from those of the first embodiment will be mainly described, elements that are substantially the same as the elements described in the first embodiment will be given the same reference numerals, and description thereof will be omitted as much as possible.

The self-generated lighting fixture according to the sixth embodiment of the present invention includes: a frame 30, an organic EL (Electro Luminescence) display panel 31 serving as a light source for illumination, and a dye sensitized transparent solar cell 95.

The frame 30 houses the organic EL panel 31 and the dye sensitized transparent solar cell 95, and is formed in a rectangular frame shape.

The organic EL panel 31 is lighted up by emitting the white light energy 68 upon receiving supply of the electric power. The organic EL panel 31 includes: a metal electrode 32, an organic electron transporting layer 33, an organic light emitting layer 34, an organic hole transporting layer 35, an ITO (indium tin oxide) transparent electrode 36, and a transparent substrate 37. The ITO transparent electrode 36, the organic hole transport layer 35, the organic light emitting layer 34, the organic electron transport layer 33, and the metal electrode 32 are stacked on the transparent substrate 37 in this order. The organic EL panel 31 radiates the white light energy 68 in such a manner that electrons carried from the metal electrode 32 through the organic electron transport layer 33 and holes carried from the ITO transparent electrode 36 through the organic hole transport layer 35 are combined in the organic light emitting layer 34, and a light emitting material of the organic light emitting layer 34 is excited by the energy resulting from this combination.

The dye sensitized transparent solar cell 95 is disposed in a light emitting direction of the organic EL panel 31. Specifically, the dye sensitized transparent solar cell 95 is formed on the surface on the opposite side of the ITO transparent electrode 36, which is one main surface of the transparent substrate 37. The dye sensitized transparent solar cell 95 is formed in a planar shape so as to cover the main surface of the transparent substrate 37. The dye sensitized transparent solar cell 95 absorbs the white light energy 68 radiated from the organic EL panel 31, and generates the photovoltaic power by the photovoltaic effect.

### (Electric Circuit)

The power control unit 112 controls the electric power to be supplied to the organic EL panel 31 and includes the commercial electric power as one of the electric powers to be controlled, and has the AC/DC converter 110 and the DC controller 111. The AC/DC converter 110 converts the commercial electric power (AC) to DC power, upon receiving supply of the commercial electric power (AC). The DC power converted by the AC/DC converter 110 is stored in the lithium ion storage battery 120 of the power storage device 121. The DC controller 111 controls so that the photovoltaic power generated by the dye sensitized transparent solar cell 95 is compatible with the organic EL panel 31. The electric power controlled by the DC controller 111 is stored in the lithium ion storage battery 120 of the power storage device 121.

The power storage device 121 includes the lithium ion storage battery 120 that stores electricity upon receiving supply of the electric power from the power control unit 112, and supplies the electric power stored in the lithium ion storage battery 120 to the organic EL panel 31. The lithium ion storage battery 120 stores electricity supplied from the AC/DC converter 110 and the DC controller 111 of the power control unit 112. The electric power stored in the lithium ion storage battery 120 is supplied to the organic EL panel 31. The electric power supplied to the organic EL panel 31 is consumed for causing the organic light emitting layer 34 of the organic EL panel 31 to emit light (lighted up).

Further, the power storage device 121 has a detecting function of detecting stop of supply of the electric power from the power control unit 112, and/or power failure, in addition to on (energizing)/off (cutoff) function of a power switch. When the stop of supply of the electric power from the power control unit 112 and/or the power failure is detected by the detecting function, the power storage device 121 has an endless function of always turning on the organic EL panel 31 by continuously supplying the electric power stored in the lithium ion storage battery 120 to the organic EL panel 31 and resuming supply of the electric power to the organic EL panel 31 upon receiving supply of the electric power generated by the dye sensitized transparent solar cell 95 by absorption of the white light energy 68 radiated from the organic EL panel 31 during the on-state.

Further, when the charged amount of the lithium ion battery 120 reaches a fully charged state upon receiving supply of the electric power from the power control unit 112, the power storage device 121, by itself, has an overcharge prevention function of stopping supply of the electric power, from the power control unit 112. Further, when supply of the electric power from the power control unit 112 is stopped by the overcharge prevention function and thereafter the electric power is consumed from the fully charged state to become storable, the power storage device 121 has a function of storing the electric power upon receiving supply of the electric power from the power control unit 112, the electric power being generated by the dye sensitized transparent solar cell 95, and when the storage amount of the lithium ion storage battery 120 is decreased to a preset remaining charged amount during this storage, the power storage device 121 has a function of resuming supply of the commercial electric power to the organic EL panel 31 upon receiving supply of the commercial electric power from the power control unit 112. Note that the setting of the remaining charged amount is the same as that in the fourth embodiment.

In the sixth embodiment of the present invention, the organic EL panel 31 radiates the white light energy 68 because the power storage device 121 supplies the commercial electric power stored in the lithium ion storage battery 120 to the organic EL panel 31 via the AC/DC converter 110. Then, the dye sensitized transparent solar cell 95 absorbs the white light energy 68 radiated from the organic EL panel 31, and generates the photovoltaic power by the photovoltaic effect. The photovoltaic power generated by the dye sensitized transparent solar cell 95 in this manner is captured into the power storage device 121 via the DC controller 111, stored in the lithium ion storage battery 120, and thereafter supplied again to the organic EL panel 31 by the power storage device 121. As a result, it is possible to radiate the white light energy 68 from the organic EL panel 31 using the photovoltaic power generated by the dye sensitized transparent solar cell 95 and to use this emission for illumination.

Further, when the stop of supply of the electric power from the power control unit 112 is detected due to some abnormality or the power failure while the power supply switch is turned on, the power storage device 121 continuously supplies the electric power stored in the lithium ion storage battery 120, to the organic EL panel 31. Thereby, it is possible to maintain the organic EL panel 31 in the on-state (lighting state of the organic EL panel 31). Further, the power storage device 121 stores electricity in the lithium ion storage battery 120 upon receiving the photovoltaic power from the power control unit 112, the photovoltaic power being generated by the dye sensitized transparent solar cell 95 using the white light energy 68 radiated from the on-state organic EL panel 31, and resumes supply of the electric power to the organic EL panel 31 therefrom. Thereby, it is possible to maintain the organic EL panel 31 in the on-state while minimizing the consumption of commercial electric power.

Further, when supply of the electric power from the power control unit 112 is stopped by the overcharge prevention function and thereafter the electric power is consumed from the fully charged state to become storable, the power storage device 121 stores electricity in the lithium ion storage battery 120 upon receiving supply of the electric power from the power control unit 112, the electric power being generated by the dye sensitized transparent solar cell 95, and when the storage amount of the lithium ion storage battery 120 is decreased to a preset remaining charged amount during this storage, the power storage device 121 resumes supply of the commercial electric power to the organic EL panel 31 upon receiving supply of the commercial electric power from the power control unit 112. Thereby, it is possible to maintain the organic EL panel 31 in the on-state, while supplementing the shortage of the charged amount by supply of the commercial electric power, the shortage of the charged amount being caused by supply of the electric power generated by the dye sensitized transparent solar cell 95.

Even if the power failure occurs while being in the lighting state of the organic EL panel 31, the organic EL panel 31 radiates the white light energy 68 upon receiving supply of the electric power continuously from the lithium ion storage battery 120, and the dye sensitized transparent solar cell 95 repeats power generation to self-generate electricity by absorption of the white light energy 68, and stores it in the lithium ion storage battery 120. Thereby, it is possible to achieve a longer life of the discharge capacity time of the lithium ion storage battery 120. Further, the organic EL panel 31 continues to radiate the white light energy 68 until the charged amount in the lithium ion storage battery 120 becomes zero as long as the power switch is not turned off (cut off). Therefore, it is possible to realize the self-generated lighting fixture having both the function as a lighting fixture responding to long-term emergency power failure and the power saving function during stop of the supply of the commercial electric power.

Note that in the sixth embodiment, the dye sensitized transparent solar cell is used as the transparent solar cell, but the transparent solar cell is not limited thereto, and transparent solar cells such as organic transparent solar cells including organic transparent thin film solar cells, transparent innovative solar cells, transparent compound-based solar cells, transparent thin-film solar cells, etc., can be widely used. Further, in the sixth embodiment, the lithium ion storage battery is used as an example of the storage battery (secondary battery), but other storage batteries (for example, a lead storage battery, a nickel storage battery, etc.) may also be used.

### INDUSTRIAL APPLICABILITY

Currently used lighting fixture does not self-generate electricity by reusing the light energy radiated from the lighting fixture itself, and therefore much electric power is required. The self-generated lighting fixture of the present invention can self-generate the electric power by reusing the self-radiated light energy. Further, by providing a transparent solar cell that absorbs light energy from a light source to self-generate electricity, stable self-power generation can be calculated without being influenced by weather, and enormous power saving becomes possible, which helps to prevent global warming.

### DESCRIPTION OF SIGNS AND NUMERALS

1 . . . Purple LED package
2 . . . Blue LED package
3 . . . Ultraviolet light LED package
10 . . . Purple LED element
11 . . . Blue LED element
17 . . . LED substrate
19 . . . Blue LED module
20 . . . purple LED module
21 . . . Purple LED module
23 . . . Ultraviolet LED module
25 . . . Titanium oxide apatite layer
26 . . . Back side lamp cover
31 . . . Organic EL panel
41 . . . LED module unit
68 . . . White light energy
73 . . . UV light energy
74 . . . Purple light energy
93 . . . Picture display panel
95 . . . Dye sensitized transparent solar cell
96 . . . External transparent solar cell
100 . . . Organic thin film transparent solar cell
105 . . . Lamp cover
110 . . . AC/DC converter
111 . . . DC controller
112 . . . Power control unit
120 . . . Lithium ion storage battery
121 . . . Electric storage device

1. A self-generated lighting fixture, comprising:
a light source for illumination that emits light upon receiving supply of electric power;
a transparent solar cell that absorbs light energy to generate electricity; and
a power control unit that controls electric power supplied to the light source and includes commercial electric power as one of electric powers to be controlled,
wherein the light source has a first light source and a second light source provided independently of each other,
the transparent solar cell absorbs a summed light energy from both the first light source and the second light source to generate electricity, and
the power control unit supplies the commercial electric power to the first light source and supplies the electric power generated by the transparent solar cell to the second light source.

2. The self-generated lighting fixture according to claim 1, wherein the second light source self-radiates light energy independently of the first light source, upon receiving supply of electric power generated by the transparent solar cell, and supplies the radiated light energy to the transparent solar cell.

3. The self-generated lighting fixture according to claim 1, wherein the second light source radiates light energy by electric power generated by the transparent solar cell, without requiring the commercial electric power.

4. The self-generated lighting fixture according to claim 1,
wherein the first light source is constituted by a first LED module in which a plurality of surface mount-type LED packages are connected,
the second light source is constituted by a second LED module in which a plurality of surface mount-type LED packages are connected, and
the transparent solar cell is formed inside of a lamp cover which is formed so as to surround and cover the first LED module and the second LED module.

5. A self-generating lighting fixture, comprising:
a light source for illumination that emits light upon receiving supply of electric power;
a mount-type substrate on which the light source is mounted;
a transparent solar cell that absorbs light energy to generate electricity; and
a power control unit that controls electric power to be supplied to the light source and includes at least commercial electric power as one of electric powers to be controlled,
wherein the light source has a first light source mounted on one main surface of the mount-type substrate, and a second light source mounted on the other main surface of the mount-type substrate so as to emit light toward an opposite side of the first light source,
the transparent solar cell absorbs light energy radiated from the first light source to generate electricity, and
the power control unit supplies the commercial electric power to the first light source, and supplies the electric power generated by the transparent solar cell to the second light source.

6. The self-generated lighting fixture according to claim 5,
wherein the first light source is constituted by a first LED module in which a plurality of surface mount-type first LED packages are connected,
the second light source is constituted by a second LED module in which a plurality of surface mount-type second LED packages are connected, and
the transparent solar cell is formed inside of a lamp cover which is formed so as to surround and cover the first LED module.

7. The self-generated lighting fixture according to claim 6, wherein a titanium oxide apatite layer is formed on an outside of a lamp cover which is formed so as to surround and cover the second LED module.

8. The self-generated lighting fixture according to claim 7, wherein the titanium oxide apatite layer is excited by UV light emitted from the second LED module to exhibit a photocatalytic function.

9. A self-generated lighting fixture, comprising:
a light source for illumination that emits light upon receiving supply of electric power;
a transparent solar cell that absorbs light energy to generate electricity;
a power control unit that controls electric power to be supplied to the light source, and includes commercial electric power as one of electric powers to be controlled; and
a power storage device that includes a storage battery storing electricity upon receiving supply of the electric power from the power control unit, and supplies the electric power stored in the power storage battery to the light source,
wherein the transparent solar cell absorbs the light energy radiated from the light source to generate electricity,
the power control unit captures the commercial electric power and the electric power generated by the transparent solar cell, and supplies the captured electric power to the power storage device, and
the power storage device has a detecting function of detecting stop of supply of the electric power from the power control unit, and/or power failure, in addition to on/off function of a power switch, and has an endless function of always turning on the light source by continuously supplying the electric power stored in the storage battery to the light source when the stop of supply of the electric power from the power control unit and/or power failure is detected by the detecting function, and resuming supply of the electric power to the light source upon receiving supply of the electric power generated by the transparent solar cell by absorption of the light energy radiated from the light source during the on state.

10. The self-generated lighting fixture according to claim 9, wherein when a charged amount of the storage battery reaches a fully charged state upon receiving supply of the electric power from the power control unit, the power storage device, by itself, has an overcharge prevention function of stopping supply of the electric power from the power control unit, and when supply of the electric power from the power control unit is stopped by the overcharge prevention function and thereafter the electric power is consumed from the fully charged state to become storable, the power storage device has a function of storing electricity upon receiving supply of the electric power from the power control unit, the electric power being generated by the transparent solar cell, and when the storage amount of the lithium ion storage batteries is decreased to a preset remaining charged amount during this storage, the power storage device has a function of resuming supply of the commercial electric power to the light source upon receiving supply of the commercial electric power from the power control unit.

11. The self-generated lighting fixture according to claim 9,
wherein the light source is constituted by an LED module in which a plurality of surface mount-type LED packages are connected,
the transparent solar cell includes a first transparent solar cell formed inside of a lamp cover which is formed so as to surround and cover the LED module, and a second transparent solar cell formed in a rear surface side radiating portion of the LED module,
the first transparent solar cell absorbs light energy radiated from the LED module to generate electricity,
the second transparent solar cell absorbs light energy of sunlight to generate electricity, and
the power storage device stores electricity in the power storage battery upon receiving supply of the electric power generated by at least one of the first transparent solar cell and the second transparent solar cell.

12. The self-generated lighting fixture according to claim 9, wherein
the light source is constituted by an organic EL panel, and the transparent solar cell is disposed in a light emitting direction of the organic EL panel, and absorbs light energy radiated from the organic EL panel to generate electricity.

13. A self-generated lighting fixture, comprising:
a light source for illumination that emits light upon receiving supply of electric power;
a panel having an irradiation target surface irradiated with light energy from the light source; and
a transparent solar cell that absorbs the light energy to generate electricity;
wherein the light source is installed obliquely with respect to an illumination target surface so that the illumination target surface of the panel is irradiated obliquely with the light energy,
the irradiation target surface of the panel is disposed outward, and
the transparent solar cell is formed in a planar shape on the irradiation target surface, and both the light energy radiated from the light source and the light energy of the sunlight are absorbed to generate electricity.

14. The self-generated lighting fixture according to claim 13, comprising:
a power control unit that controls electric power supplied to the light source and includes commercial electric power as one of electric powers to be controlled; and
a power storage device that includes a power storage battery storing electricity upon receiving supply of the electric power from the power control unit, and supplies the electric power stored in the power storage battery to the light source,
wherein the power storage device has a detecting function of detecting stop of supply of the electric power from the power control unit, and/or power failure, in addition to on/off function of a power switch, and has an endless function of always turning on the light source by continuously supplying the electric power stored in the storage battery to the light source when the stop of supply of the electric power from the power control unit and/or power failure is detected by the detecting function, and resuming supply of the electric power to the light source upon receiving supply of the electric power generated by the transparent solar cell by absorption of the light energy radiated from the light source during the on state.

15. The self-generated lighting fixture according to claim 14, wherein when a charged amount of the power storage battery reaches a fully charged state upon receiving supply of the electric power from the power control unit, the power storage device, by itself, has an overcharge prevention function of stopping supply of the electric power from the power control unit, and when supply of the electric power from the power control unit is stopped by the overcharge prevention function and thereafter the electric power is consumed from the fully charged state to become storable, the power storage device has a function of storing electricity upon receiving supply of the electric power generated by the transparent solar cell, and when the storage amount of the power storage battery is decreased to a preset remaining charged amount during this storage, the power storage device has a function of resuming supply of the commercial electric power to the light source upon receiving supply of the commercial electric power from the power control unit.

16. A self-generated lighting fixture, comprising:
a light source for illumination that emits light upon receiving supply of electric power;
a transparent solar cell that absorbs light energy to generate electricity; and
a power control unit that controls electric power to be supplied to the light source, and includes commercial electric power as one of electric powers to be controlled,
wherein the transparent solar cell absorbs light energy radiated from the light source to generate electricity,
the power control unit supplies summed electric power of the commercial electric power and the electric power generated by the transparent solar cell, to the light source, and
the light source radiates light energy by supply of the summed electric power.
